(19) United States
(12) Patent Application Publication
(10) Pub. No.: US 2010/0296541 A1
(43) Pub. Date: Nov. 25, 2010

(54) SEMICONDUCTOR LASER DIODE

(76) Inventor: Tougo NAKATANI, Hyogo (JP)

Correspondence Address: MCDERMOTT WILL & EMERY LLP, 600 13TH STREET, NW, WASHINGTON, DC, 20005-3096, US

(21) Appl. No.: 12/696,593

(22) Filed: Jan. 29, 2010

(30) Foreign Application Priority Data
May 25, 2009 (JP) 2009-124967

(51) Int. Cl. H01S 5/06; H01S 5/00

(52) U.S. Cl. 372/46.01

(57) ABSTRACT

A semiconductor laser diode includes a semiconductor multilayer structure including a first cladding layer of n-type conductivity, an active layer, and a second cladding layer of p-type conductivity having a ridge portion in an upper portion, which are sequentially formed on a substrate; a current blocking layer formed on the semiconductor multilayer structure, and having an opening exposing an upper surface of the ridge portion; an ohmic electrode formed on the upper surface of the ridge portion; an interconnect formed on the semiconductor multilayer structure to be electrically connected to the ohmic electrode; and a pad electrode formed in a region on one side of the ridge portion on the interconnect. The interconnect connects the pad electrode to the ohmic electrode through at least two current channels.

### CROSS-REFERENCE TO RELATED APPLICATION

This application claims priority to Japanese Patent Application No. 2009-124967 filed on May 25, 2009, the disclosure of which including the specification, the drawings, and the claims is hereby incorporated by reference in its entirety.

### BACKGROUND

The present disclosure relates to semiconductor laser diodes; and more particularly to semiconductor laser diodes, which enable high-speed responses with currents generated by superimposing high-frequency signals.

Semiconductor laser diodes are widely used in various fields. For example, they are used for recorders, personal computers (PCs), automobiles, and communications. In particular, semiconductor laser diodes using gallium nitride semiconductors (e.g., made of AlₓGa_{y}In_{1-x-y}N, where 0≦x, y≦1, and 0≦x+y≦1) can obtain blue laser light with a wavelength of 405 nm band, and thus are used as optical pick-up light for Blu-ray Discs (Blu-ray Disc is a registered trademark). Semiconductor laser diodes used in such fields need to accurately reproduce high-speed record signals to realize high-speed recording. Therefore, there is a need for semiconductor laser diodes operating at high speed.

High-speed operating semiconductor laser diodes are required not only as blue laser diodes but also particularly as laser diodes for communications. For example, a laser diode with reduced parasitic capacitance as shown in Japanese Patent Publication No. H03-206678 (Patent Document 1) is known.

FIG. 10 illustrates an example of a conventional semiconductor laser diode shown in Patent Document 1. As shown in FIG. 10, the conventional semiconductor laser diode includes an n-type InP layer 202, an n-type InGaAsP layer 203, and an n-type InP layer 204, which are sequentially formed on an n-type InP substrate 201; as well as a buried mesa groove 205. The semiconductor laser diode further includes a p-type InP layer 206, an i-type InP layer 207, and an n-type InP layer 208, which are sequentially formed; as well as a p-type InP layer 209 and a p-type InGaAsP layer 210, which are sequentially formed.

A mesa groove 211 for separating pnpn junctions is formed outside the buried mesa groove 205, and an SiO₂ film 212 is formed on the mesa groove 211. An upper portion of a mesa portion (a ridge portion) in the SiO2 film 212 is provided with an opening for contact, and an ohmic metal layer 213 is formed to fill the opening.

In this example, a metal electrode 214 bridges the mesa groove 211 between the metal electrode 214 and the ohmic metal layer 213 to form an air layer between the metal electrode 214 and the ohmic metal layer 213. This reduces parasitic capacitance of the metal electrode 214 to provide a semiconductor laser diode capable of high-speed responses.

### SUMMARY

However, the present inventor found that the following problems arise when the above-described conventional semiconductor laser diode is driven by a current including high-speed signals, for example, when high-frequency signals with frequencies of 400 MHz are superimposed.

To be specific, when a semiconductor laser diode is driven by a current including a high-frequency component, the supplied current reaches a ridge stripe through an electrode of the semiconductor laser diode, thereby supplying the current to an underlying active layer to obtain laser light.

The positional relationship between the ridge stripe and a wire for supplying a current to the electrode will be described below.

In general, a semiconductor laser diode has a plane rectangular shape with a long side in the extending direction of a laser cavity. As a mounting method of the semiconductor laser diode, to which a current is supplied; there are so-called junction-up mounting, and junction-down mounting. In the junction-up mounting, a single wire is connected to an anode electrode (a p-side electrode) of the semiconductor laser diode, and a cathode electrode (an n-side electrode) is connected to a heat radiator. In the junction-down mounting, an anode electrode (a p-side electrode) is connected to a heat radiator, and a single wire is connected to a cathode electrode (an n-side electrode). The former is primarily employed for laser diodes for communications, as well as laser diodes for reproduction and blue laser diodes for record/reproduction in the optical disk field. The latter is employed for two-wavelength semiconductor laser diodes for record in the optical disk field.

In each of the junction-up mounting and the junction-down mounting, only a single wire is connected to the semiconductor laser diode.

For example, in the junction-up mounting, a current, which is supplied from a wire connected to the anode electrode of the semiconductor laser diode, easily flows through the shortest channel connecting a wire bonding position (a pad electrode) to the ridge stripe extending in a longitudinal direction of a cavity. When a current including a high-frequency component is supplied to the wire, a current being in a different phase is supplied to the ridge stripe, since the current flows through a different channel from the pad electrode to the ridge stripe. The supply of the current in the different phase causes non-uniform gain distribution in an active layer under the ridge stripe, and a change in a refractive index. Since there is a difference in the intensity of laser light generated inside the active layer, deterioration in a transient optical response occurs.

In view of the foregoing, the conventional example will be discussed below.

In the semiconductor laser diode according to the conventional example shown in FIG. 10, the bonding pad is formed on one facet in the longitudinal direction of the cavity. A metal electrode is formed on the ridge stripe extending from the one facet to the other facet. In this form, the one facet which is near the bonding pad, and the other facet which is far from the bonding pad have different current density, when a high-frequency current is applied. As such, when non-uniform distribution of supply current density occurs, non-uniform gain distribution is caused in the active layer within the laser diode. In the semiconductor laser diode shown in FIG. 10, the facet near the bonding pad has the maximum light gain, and the facet far from the bonding pad has the minimum light gain. With such gain distribution, intensity of laser light generated at the facet near the bonding pad differs from that at the facet far from the bonding pad. As a result, the laser light generated at the both facets interferes with each other to cause deterioration in transient response properties such as a delay.

In particular, this phenomenon greatly affects a record signal of an optical disk system. When recording information on an optical disk in an optical disk system, record signals have rectangular signals with various widths. When a current including the rectangular signals drives a laser diode, and the state of the diode greatly changes from an OFF state to an ON state, overshoot occurs in association with relaxation oscillation through the progress of interaction between carriers and photons until laser light reaches a given light output. Furthermore, due to non-uniform current distribution in the laser diode with respect to the above-described high-frequency signals, the behavior of the carriers and photons becomes more complex to cause deterioration in a response waveform.

On the other hand, when the state of a diode greatly changes from a given light output state to an OFF state, undershoot occurs to cause, like the overshoot, deterioration in a response waveform of a high-frequency signal. This phenomenon is clearly observed in blue laser diodes. Overshoot and undershoot increase in the laser diode due to strength distribution of the injected current to deteriorate recording quality of an optical disk. Therefore, in order to reduce overshoot and undershoot, various attempts have been made in an electrical circuit such as a filter circuit (hereinafter referred to as a “snubber circuit”). However, being provided between a laser diode and a driver circuit, a snubber circuit is likely to be affected by the shape and position of a channel between the laser diode and the driver circuit. This causes difficulty in designing the snubber circuit.

It is an objective of the present disclosure to solve the above-described problem and to provide a semiconductor laser diode having excellent high-speed response properties.

In order to achieve the objective, the semiconductor laser diode of the present disclosure has at least two separate current channels from a pad electrode to an electrode on a ridge stripe.

To be specific, the semiconductor laser diode of the present disclosure includes a semiconductor multilayer structure including a first cladding layer of a first conductivity type, an active layer, and a second cladding layer of a second conductivity type having a ridge portion in an upper portion, which are sequentially formed on a substrate; a current blocking layer formed on the semiconductor multilayer structure, and having an opening exposing an upper surface of the ridge portion; an ohmic electrode formed on the upper surface of the ridge portion; an interconnect formed on the semiconductor multilayer structure to be electrically connected to the ohmic electrode; and a pad electrode formed in a region on one side of the ridge portion on the interconnect. The interconnect connects the pad electrode to the ohmic electrode through at least two current channels.

According to the semiconductor laser diode of the present disclosure, a signal current, which is supplied from the outside through the pad electrode and includes a high-frequency component, is injected into the ridge portion through a wire having at least two current channels. Thus, the supplied signal current is uniformly injected into the ridge portion. This reduces non-uniform gain distribution in an active layer to stabilize intensity of laser light generated in the active layer. Furthermore, when a current is uniformly supplied to the ridge portion, a refractive index in a semiconductor multilayer structure can be prevented from changing to achieve uniform light distribution. This reduces deterioration in an optical response waveform caused by interference with the light propagating the ridge portion.

In the semiconductor laser diode of the present disclosure, the interconnect may be a metal film covering the semiconductor multilayer structure including the ridge portion. The metal film may have at least one opening for electrically disconnecting the pad electrode from the ohmic electrode.

This facilitates formation of a wire having at least two current channels.

In this case, the opening may be formed along with the ridge portion. A length of the opening along the ridge portion may be a quarter or more of a length of the metal film along the ridge portion.

In the semiconductor laser diode of the present disclosure, the ridge portion may be interposed between two grooves formed in parallel to each other in the semiconductor multilayer structure. A formation region of the pad electrode in the interconnect and the upper surface of the ridge portion are at a same height from an upper surface of the substrate.

This reduces stress caused by the wire applied to the ridge portion to provide a semiconductor laser diode with high reliability and high quality of a response waveform.

In the semiconductor laser diode of the present disclosure, the substrate may be made of gallium nitride. The first cladding layer and the second cladding layer may be made of aluminum gallium nitride.

The difference in lattice constants between aluminum gallium nitride (AlGaN) and gallium nitride (GaN) is large. The stress applied to the inside of the semiconductor multilayer structure such as the active layer and the ridge portion is large. Therefore, the present disclosure is advantageous as a semiconductor laser diode using semiconductor materials having a large difference in lattice constants.

In the semiconductor laser diode of the present disclosure, the semiconductor multilayer structure may be cleaved in a direction intersecting the ridge portion and may have two facets facing each other. The interconnect may be arranged near the two facets and may electrically connect the ohmic electrode to the pad electrode. The pad electrode may be formed in a region between a front facet of the two facets, which emits laser light, to a center of the ridge portion.

In this structure, even when a large amount of current needs to be supplied near a front facet of the ridge portion, a constant current can be supplied to the ridge portion apart from the pad electrode. This reduces non-uniformity in gain distribution in the active layer to stabilize intensity of laser light generated in the active layer.

As the foregoing, in semiconductor laser diode according to the present disclosure, a current supplied to the ridge portion and including a high-frequency component becomes uniform to reduce strains generated in the ridge portion. This provides the semiconductor laser diode with less deterioration in an optical response waveform and with high-speed response properties.

### BRIEF DESCRIPTION OF THE DRAWINGS

FIG. 1 is a plan view of a semiconductor laser diode according to a first example embodiment.

FIG. 2A is a cross-sectional view taken along the line IIa-IIa in FIG. 1.

FIG. 2B is a cross-sectional view taken along the line IIb-IIb in FIG. 1.

FIG. 3A is a graph illustrating current strength of the semiconductor laser diode according to the first example embodiment, where an opening for an electrode has a length which is about a quarter of that of a p-side electrode.

FIG. 3B is a graph illustrating current strength according to a comparative example, where the p-side electrode does not include an opening for an electrode.

FIG. 4 is a plan view of the semiconductor laser diode according to a variation of the first example embodiment.

FIG. 5A is a cross-sectional view taken along the line Va-Va in FIG. 4.

FIG. 5B is a cross-sectional view taken along the line Vb-Vb in FIG. 4.

FIG. 6A is a graph illustrating current strength of the semiconductor laser diode according to a variation of the first example embodiment, where an opening for an electrode has a length which is about a half of that of a p-side electrode.

FIG. 6B is a graph illustrating dependence of current strength of laser light on the length of the opening for the electrode.

FIG. 7 is a plan view of a semiconductor laser diode according to a second example embodiment.

FIG. 8A is a cross-sectional view taken along the line VIIIa-VIIIa in FIG. 7.

FIG. 8B is a cross-sectional view taken along the line VIIIb-VIIIb in FIG. 7.

FIG. 9 is a graph illustrating current strength of the semiconductor laser diode according to the second example embodiment, where a wire is formed at a distance about L/4 from a front facet.

FIG. 10 is a perspective view of a conventional semiconductor laser diode.

### DETAILED DESCRIPTION

### First Example Embodiment

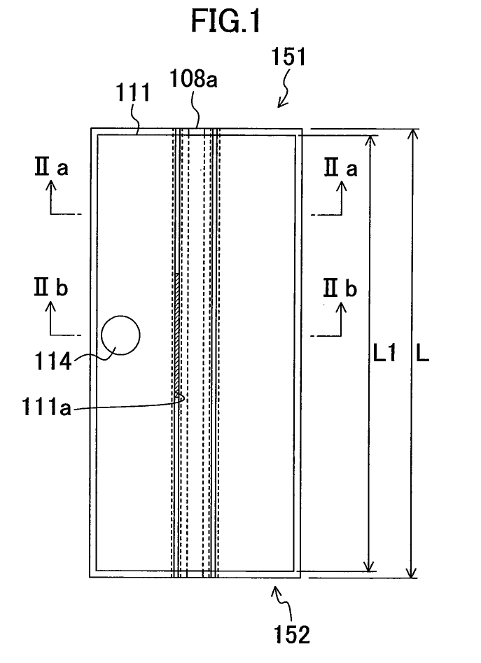

A first example embodiment will be described hereinafter with reference to FIG. 1.

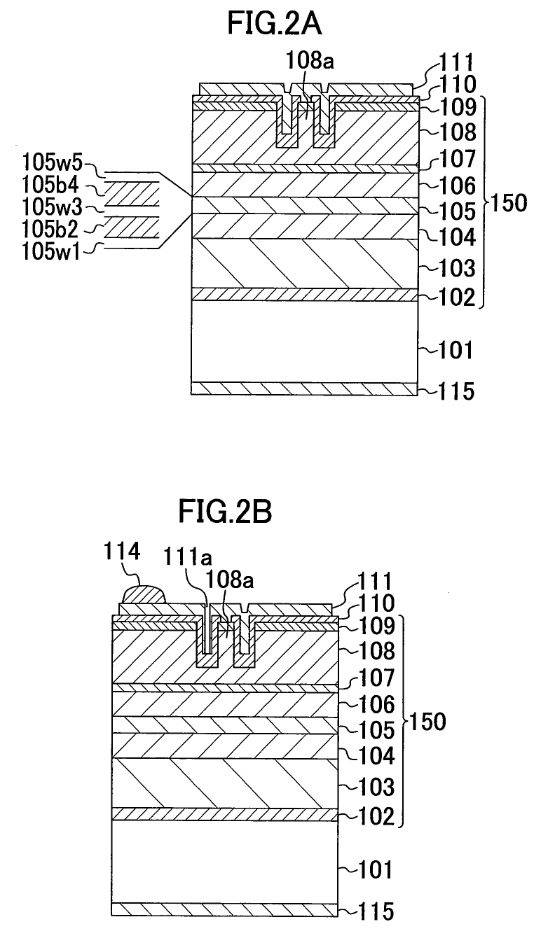

As shown in FIGS. 1, 2A and 2B, the semiconductor laser diode according to the first example embodiment includes a semiconductor multilayer structure 150 including an n-type buffer layer 102, an n-type cladding layer 103, an n-type optical guide layer 104, an active layer 105, a p-type interlayer 106, a p-type cap layer 107, a p-type cladding layer 108, and a p-type contact layer 109, which are sequentially formed on a main surface of a substrate 101, which is made of n-type GaN with a thickness of about 100 μm, and doped with n-type impurities such as silicon (Si).

In an upper portion of the p-type cladding layer 108, a ridge portion 108a with a width of about 1.5 μm is formed to be interposed between two grooves, which penetrate the p-type contact layer 109 and extend in parallel to each other with spacing.

On the semiconductor multilayer structure 150, a current blocking layer 110 is formed, which includes an opening exposing an upper surface of the ridge portion 108a. The current blocking layer 110 is made of, for example, silicon dioxide (SiO₂) with a thickness of about 300 nm. A p-side electrode 111 is formed on the current blocking layer 110 to come into contact with the p-type contact layer 109 exposed from the opening of the current blocking layer 110.

The n-type buffer layer 102 is made of, for example, GaN with a thickness of about 2.0 μm, the n-type cladding layer 103 is made of, for example, AlGaN with a thickness of about 2.5 μm, and the n-type optical guide layer 104 is made of GaN with a thickness of about 200 nm. The active layer 105 has a multiple quantum well structure including well layers 105w1, 105w3, and 105w5, as well as barrier layers 105b2 and 105b4. Each of the well layers is made of InGaN with a thickness of about 5 nm, and each of the barrier layers is made of InGaN with a thickness of about 10 nm. The p-type interlayer 106 is made of, for example, InGaN with a thickness of about 100 nm. The p-type cap layer 107 and the p-type cladding layer 108 are made of, for example, AlGaN with a thickness of about 10 nm and about 500 nm, respectively. The p-type cap layer 107 has a function of efficiently confining electrons in the active layer 105. The p-type contact layer 109 is made of, for example, GaN with a thickness of about 50 nm.

As long as the group III nitride semiconductor layers constituting the semiconductor multilayer structure 150 function as a semiconductor laser diode, the configurations of the layers are not limited to what is described above. The semiconductor multilayer structure 150 is formed so that a chip length (a cavity length) L is about 800 and a chip width is about 250 μm.

In the first example embodiment, both sides of the ridge portion 108a in the p-type cladding layer 108 and the p-type contact layer 109 remain without being removed. The both sides function as shock-absorbing layers when a chip-form laser diode is mounted in a system or the like. This reduces damage to the laser chip due to the mounting to achieve high reliability for a long period.

On the current blocking layer 110, the p-side electrode 111 is formed, which is electrically connected to a p-type contact 109 above the ridge portion 108a, and in which palladium (Pd), platinum (Pt), titanium (Ti), and gold (Au) layers are sequentially stacked. A wire 114 made of, e.g., Au for supplying a current to the ridge portion 108a is connected to a region on one side of the ridge portion on the p-side electrode 111.

The p-side electrode 111 covers an upper surface of the current blocking layer 110, thereby functioning as a metal interconnect for electrically connecting an ohmic electrode, which is ohmic-connected to the p-type contact layer 109 on the ridge portion 108a, to the pad electrode, which serves as a bonding region of the wire 114 on the one side of the ridge portion 108a. The ohmic electrode, the pad electrode, and the metal interconnect may be made of different metals. The ohmic electrode may be formed at least on the upper surface of the ridge portion 108a, or near the ridge portion 108a including the upper surface. The electrode pad may be formed on one side of the ridge portion 108a, at least in a region to which the wire 114 is bonded.

In the first example embodiment, as shown in FIG. 1, the connecting portion of the wire 114 is provided near the center of the cavity.

Furthermore, in a region of the p-side electrode 111 between the wire 114 and the ridge portion 108a, an opening 111a for an electrode is formed, which is longer than the radius of the wire and has a length of about L1/4, where a length of the p-side electrode 111 in direction parallel to the ridge portion 108a is L1. The opening 111a exposes the current blocking layer 110. The opening 111a disconnects the shortest channel of a current flowing between the ohmic electrode on the ridge portion 108a and the wire 114. This reduces non-uniform supply of a signal current, which comes from the wire 114 and includes a high-frequency component, to the ridge portion 108a. As such, the opening 111a is provided in the p-side electrode 111, thereby enabling uniform current supply to the ridge portion 108a to reduce changes in a refractive index and fluctuations of gain caused by the non-uniform current supply. This achieves a uniform optical response waveform. As a result, distortion of a transient optical waveform can be reduced.

On a surface (a back surface) of the substrate 101, which is opposite to the n-type buffer layer 102, an n-side electrode 115 is formed, in which titanium (Ti), platinum (Pt), and gold (Au) layers are sequentially stacked.

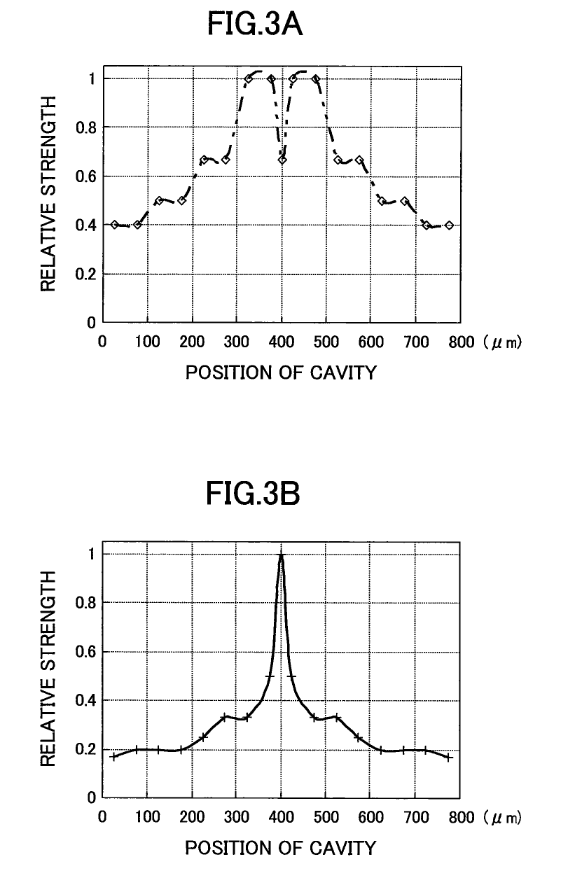

FIG. 3A illustrates current strength of the semiconductor laser diode according to the first example embodiment in the ridge portion 108a. As a comparative example, FIG. 3B illustrates current strength of a semiconductor laser diode, which does not include the opening 111a in the p-side electrode 111. In the graph, the “position of cavity” represented by the horizontal axis denotes a distance from a back facet 152 of two facets of the cavity facing each other to a front facet 151 emitting laser light. As shown in FIG. 3A, where the opening 111a is provided, the difference in the current strength in the ridge portion 108a is smaller than the difference where the opening 111a is not provided as shown in FIG. 3B. This is because, by providing the opening 111a, the shortest current channel between the wire 114 and the ridge portion 108a is disconnected to divert the supplied current from the opening 111a.

### Variation of First Example Embodiment

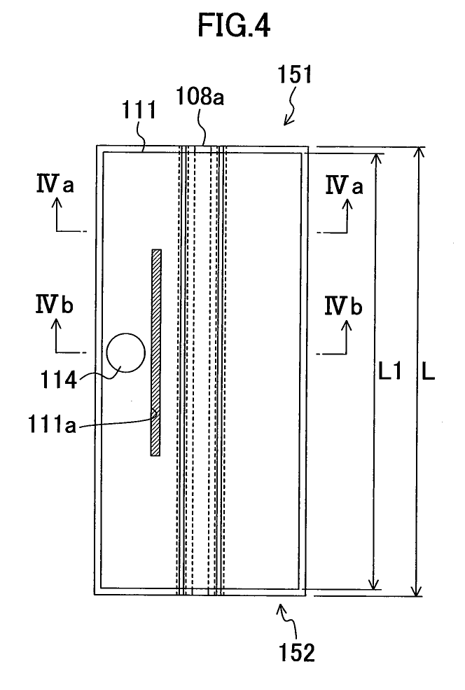

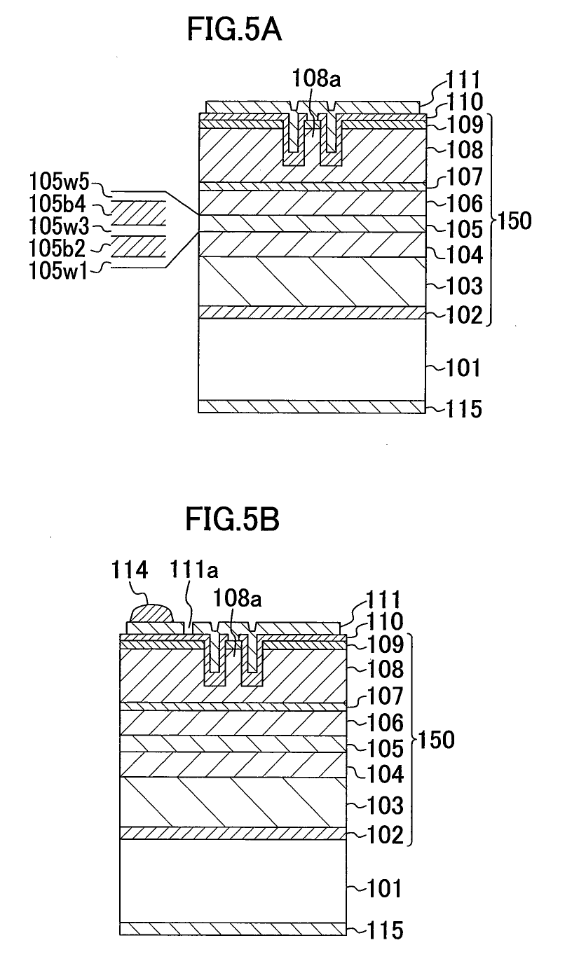

A variation of the first example embodiment will be described hereinafter with reference to FIGS. 4, 5A, and 5B. In FIGS. 4 and 5, the same reference characters as those shown in FIGS. 1 and 2 are used to represent equivalent elements, and the explanation thereof will be omitted.

As shown in FIG. 4, in the semiconductor laser diode according to this variation, the opening 111a provided in the p-side electrode 111 has a length, which is about a half of a length L1 of a p-side electrode, that is, about L1/2.

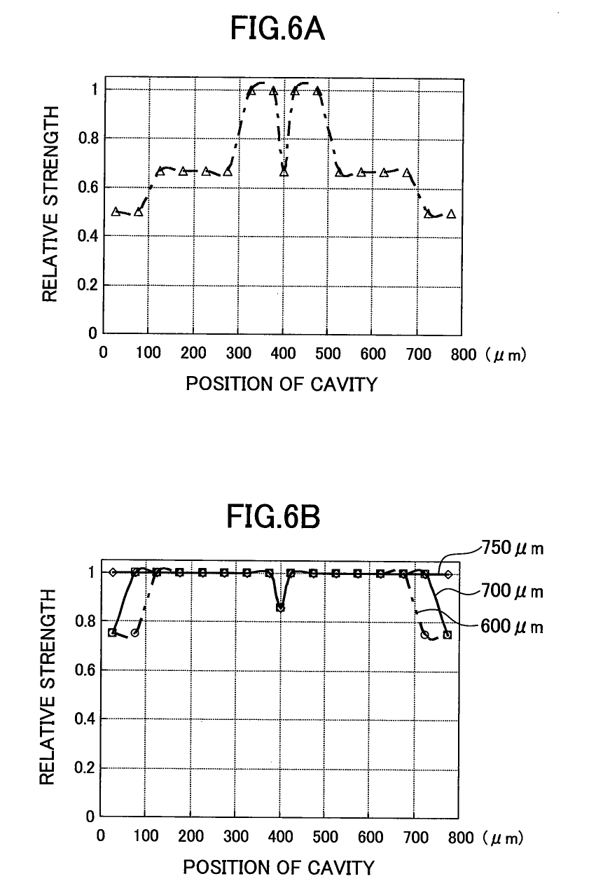

FIG. 6A illustrates current strength of the semiconductor laser diode according to this variation in the ridge portion 108a. As shown in FIG. 6A, it is found that the difference in the current strength in the ridge portion 108a is smaller than that in the first example embodiment shown in FIG. 3A, since the opening length of the opening 111a in this variation is greater than that in the first example embodiment.

In this variation, the length of the opening 111a is formed to be about a half of the length L1 of the p-side electrode 111. As shown in FIG. 6B, when the length of the opening 111a further increases, the difference in the current strength further decreases. As a result, a more excellent optical response waveform can be obtained.

However, when the opening 111a is too long, the current supplied from the wire 114 concentrates near the both facets of the cavity. The current concentration generates heat near the both facets. The localized heat generation near the both facets increases stress applied to the active layer 105 to cause a change in a refractive index. This causes distortion of a spread angle of laser light. Furthermore, the heat increases an oscillation wavelength to enhance light absorption near the facets. This results in further heat generation and light absorption, and eventually leads to a damage in the facets. Therefore, care should be taken to determine the length of the opening 111a.

With respect to the distances between the opening 111a and the wire 114, and between the opening 111a and the ridge portion 108a, when the opening 111a is formed near the ridge portion 108a, stress caused by providing the opening 111a in the p-side electrode 111 is applied to the ridge portion 108a. The stress changes the refractive index, thereby causing distortion of the spread angle of the laser light. Thus, as shown in FIGS. 4 and 5B, the opening 111a is preferably formed apart from the ridge portion 108a.

### Second Example Embodiment

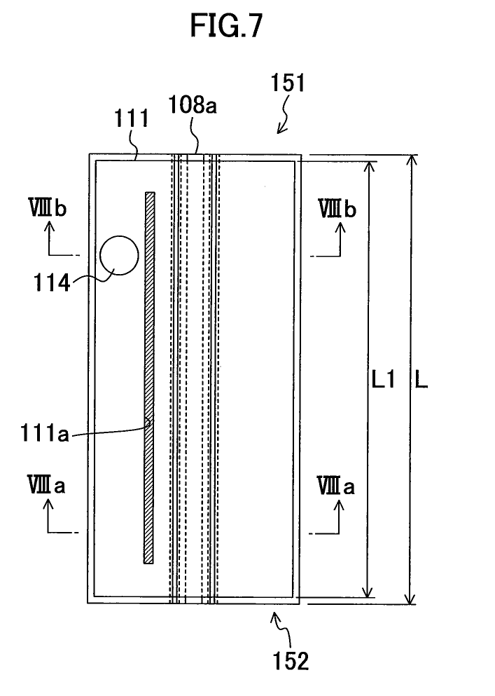

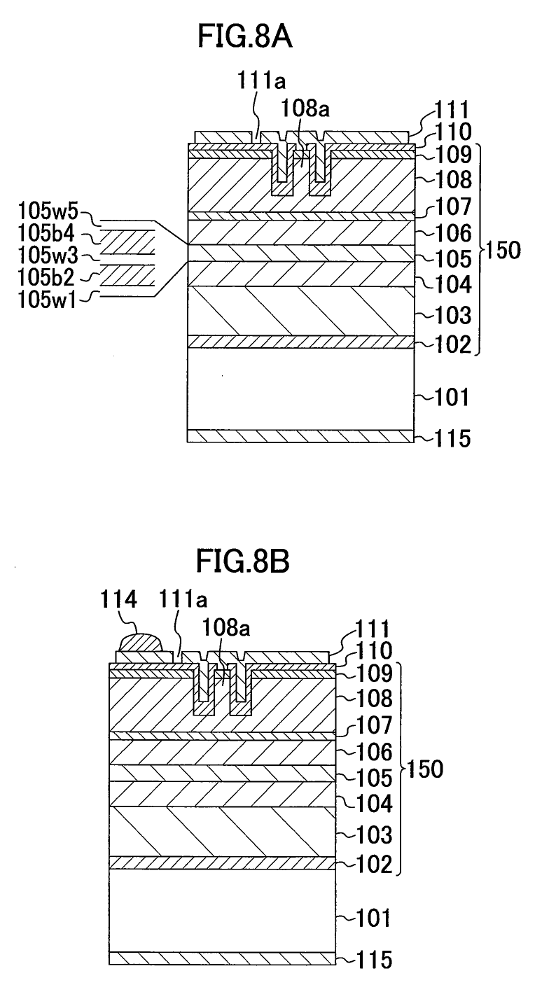

A second example embodiment will be described hereinafter with reference to FIGS. 7, 8A, and 8B. In FIGS. 7, 8A, and 8B, the same reference characters as those shown in FIGS. 1 and 2 are used to represent equivalent elements, and the explanation thereof will be omitted.

As shown in FIG. 7, in the semiconductor laser diode according to the second example embodiment, in order to obtain a maximum light output at a high temperature and a high output, light reflectivity Rf at the front facet 151 of the cavity and light reflectivity Rr at the back facet 152 have relationship represented by the formula Rf<Rr.

With this configuration, since the reflectivity is low at the front facet 151 of the cavity, and more light is emitted from the laser diode. This reduces the amount of light returning to the cavity to disable light amplification. Therefore, a large amount of current supply is required near the front facet 151 to convert the supplied current into light.

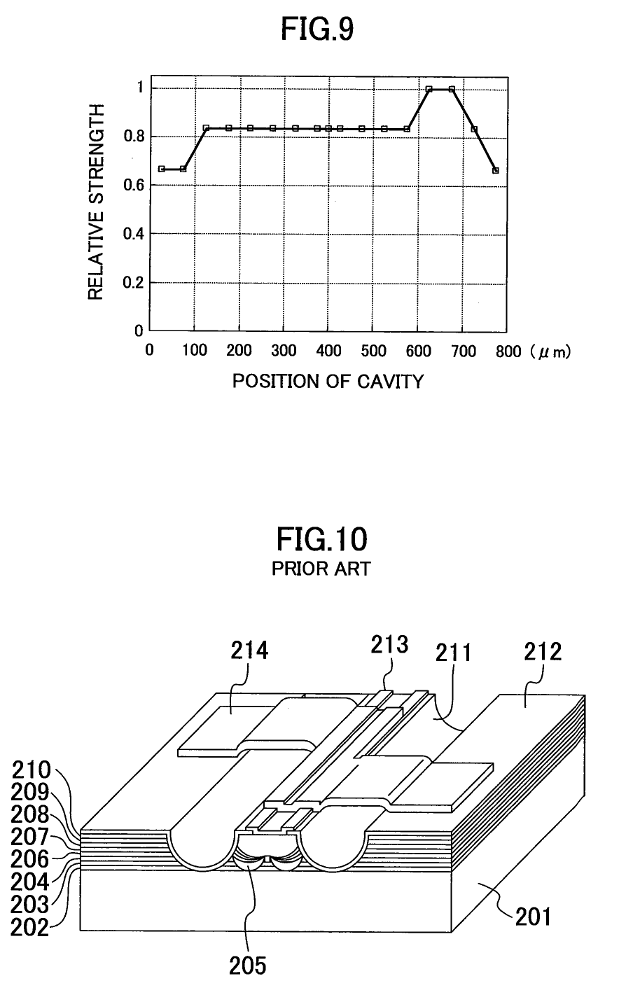

In the second example embodiment, both ends of the opening 111a extend to the proximity of the front facet 151 and the back facet 152, and the wire 114 is connected to the front facet 151 having low facet reflectivity, specifically, at a distance about a quarter of the cavity length L (i.e., about L/4) from the front facet 151. As shown in FIG. 9, this enables a large amount of current supply to the ridge portion 108a near the front facet 151, which requires a large amount of current supply. To the other portions of the ridge portion 108a, a current having almost uniform strength can be supplied. As a result, a semiconductor laser diode can be realized, which obtains an excellent optical response waveform even in operation at a high temperature and a high output.

In the second example embodiment, the connecting portion of the wire 114 is located at a distance L/4 from the front facet 151. However, the location is not limited thereto, as long as the positional relationship between the connecting portion of the wire 114, and the opening 111a is set so that the opening 111a has a length greater than the radius of the wire 114, and is provided between the wire 114 and the ridge portion 108a, in view of the relationship between the reflectivity Rf and Rr.

Furthermore, the present disclosure is not limited to gallium nitride semiconductor laser diodes, but also applicable to all semiconductor laser diodes employing junction-up mounting, in which the wire 114 is connected to the p-side electrode 111.

In each embodiment, the p-side electrode 111 is provided with two current channels, but may be provided with three or more channels. That is, for example, two or more openings 111a may be provided in the p-side electrode 111 between the wire 114 and the ridge portion 108a, as long as distribution of current injected into the ridge portion 108a can be controlled.

As described above, the semiconductor laser diode according to the present disclosure provides a high-quality and high-speed optical response even at a high temperature and a high output, and thus is particularly useful as a semiconductor laser diode or the like, which performs high-speed responses with a current with superimposed high-frequency signals.

What is claimed is:

1. A semiconductor laser diode, comprising:
a semiconductor multilayer structure including a first cladding layer of a first conductivity type, an active layer, and a second cladding layer of a second conductivity type having a ridge portion in an upper portion, which are sequentially formed on a substrate;
a current blocking layer formed on the semiconductor multilayer structure, and having an opening exposing an upper surface of the ridge portion;
an ohmic electrode formed on the upper surface of the ridge portion;
an interconnect formed on the semiconductor multilayer structure to be electrically connected to the ohmic electrode; and
a pad electrode formed in a region on one side of the ridge portion on the interconnect,
wherein the interconnect connects the pad electrode to the ohmic electrode through at least two current channels.

2. The semiconductor laser diode of claim 1, wherein
the interconnect is a metal film covering the semiconductor multilayer structure including the ridge portion, and
the metal film has at least one opening for electrically disconnecting the pad electrode from the ohmic electrode.

3. The semiconductor laser diode of claim 2, wherein
the opening is formed along with the ridge portion, and
a length of the opening along the ridge portion is a quarter or more of a length of the metal film along the ridge portion.

4. The semiconductor laser diode of claim 1, wherein
the ridge portion is interposed between two grooves formed in parallel to each other in the semiconductor multilayer structure, and
a formation region of the pad electrode in the interconnect and the upper surface of the ridge portion are at a same height from an upper surface of the substrate.

5. The semiconductor laser diode of claim 1, wherein
the substrate is made of gallium nitride, and
the first cladding layer and the second cladding layer are made of aluminum gallium nitride.

6. The semiconductor laser diode of claim 1, wherein
the semiconductor multilayer structure is cleaved in a direction intersecting the ridge portion and has two facets facing each other,
the interconnect is arranged near the two facets and electrically connects the ohmic electrode to the pad electrode, and
the pad electrode is formed in a region between a front facet of the two facets, which emits laser light, to a center of the ridge portion.
